(19) United States
(12) Patent Application Publication
(10) Pub. No.: US 2025/0054850 A1
(43) Pub. Date: Feb. 13, 2025

(54) SEMICONDUCTOR PACKAGE HAVING A CORE MODULE

(71) Applicant: SAMSUNG ELECTRONICS CO., LTD., SUWON-SI (KR)

(72) Inventors: Bongsoo Kim, Suwon-si (KR); Chobi Kim, Suwon-si (KR); Pyunghwa Han, Suwon-si (KR)

(21) Appl. No.: 18/786,824

(22) Filed: Jul. 29, 2024

(30) Foreign Application Priority Data
Aug. 8, 2023 (KR) 10-2023-0103697

(51) Int. Cl. H01L 23/498; H01L 23/00; H01L 23/31

(52) U.S. Cl. CPC H01L 23/49827; H01L 23/3107; H01L 23/49822; H01L 24/20; H01L 23/49816; H01L 24/08; H01L 2224/08225; H01L 2224/214

(57) ABSTRACT

A semiconductor package includes a first substrate, a first semiconductor device disposed on the first substrate, a dummy substrate disposed on the first substrate, spaced apart from a side surface of the first semiconductor device, and surrounding the first semiconductor device, a core module disposed in the dummy substrate, and an encapsulant surrounding the first semiconductor device and in contact with the dummy substrate, wherein the core module includes a core wiring and a module substrate, the core module is disposed on the first substrate, and a side surface of the core module is surrounded by and spaced apart from an inner side surface of the dummy substrate, and the encapsulant is disposed between the dummy substrate and the side surface of the core module.

### CROSS-REFERENCE TO RELATED APPLICATION

This application is based on and claims priority under 35 U.S.C. § 119 to Korean Patent Application No. 10-2023-0103697, filed on Aug. 8, 2023, in the Korean Intellectual Property Office, the disclosure of which is incorporated by reference herein in its entirety.

### TECHNICAL FIELD

The inventive concept relates to a semiconductor package including a core module.

### DESCRIPTION OF RELATED ART

As demand for electronic devices has increased, a need for compact and light electronic components has likewise increased. To make electronic components compact and light, semiconductor packages may be mounted on the electronic components. These semiconductor packages may be small in volume and be capable of processing a large amount of data.

Panel Level Packaging (PLP) is a technique for semiconductor packaging at a panel level, which may be realized in a large format. A panel-level semiconductor structure may be divided into individual packages. Accordingly, the panel-level semiconductor structure may be an efficient process for manufacturing semiconductor packages.

### SUMMARY

The inventive concept provides a semiconductor package with one or more core modules.

The objective of the inventive concept is not limited to those mentioned herein, and other objectives that are not mentioned will be clearly understood by those skilled in the art from the following descriptions.

According to an aspect of the inventive concept, there is provided a semiconductor package including a first substrate, a first semiconductor device disposed on the first substrate, a dummy substrate disposed on the first substrate, spaced apart from a side surface of the first semiconductor device, and surrounding the first semiconductor device, a core module disposed in the dummy substrate, and an encapsulant surrounding the first semiconductor device and in contact with the dummy substrate, wherein the core module includes a core wiring and a module substrate, the core module is disposed on the first substrate, and a side surface of the core module is surrounded by and spaced apart from an inner side surface of the dummy substrate, and the encapsulant is disposed between the dummy substrate and the side surface of the core module.

According to another aspect of the inventive concept, there is provided a semiconductor package including a first substrate, a first semiconductor device disposed on the first substrate, a core structure disposed on the first substrate, spaced apart from a side surface of the first semiconductor device, and surrounding the first semiconductor device, and an encapsulant surrounding the first semiconductor device and in contact with the core structure, wherein the core structure includes a core module and a dummy substrate, the core module including a core wiring and a module substrate, the core module is disposed on the first substrate, a side surface of the core module is surrounded by and spaced apart from an inner side surface of the dummy substrate, and the encapsulant is disposed between the dummy substrate and the side surface of the core module, the dummy substrate facing the side surface of the core module, the first semiconductor device has a quadrangular shape, and the core structure has a frame-like shape with the first semiconductor device at a center portion thereof, and the core module is provided on two or more side portions of the core structure that respectively face side surfaces of the first semiconductor device.

According to another aspect of the inventive concept, there is provided a semiconductor package including a first redistribution structure, a first semiconductor device disposed on the first redistribution structure, a core structure disposed on the first redistribution structure, spaced apart from a side surface of the first semiconductor device in a lateral direction, and surrounding the first semiconductor device, the lateral direction being a horizontal direction, an encapsulant surrounding the first semiconductor device and in contact with the core structure, and a second redistribution structure located on the encapsulant and electrically connected to the core structure, wherein the core structure includes a plurality of core modules and a dummy substrate, each core module of the plurality of core modules including a core wiring and a module substrate, the core wiring being arranged in a plurality of rows and a plurality of columns in a plan view parallel to the first redistribution structure and including a core pattern and a core via, an upper surface of the module substrate is coplanar with an upper surface of the dummy substrate, the plurality of core modules are disposed on the first redistribution structure, and side surfaces of the plurality of core modules are surrounded by and spaced apart from inner side surfaces of the dummy substrate, the encapsulant is disposed between the dummy substrate and the side surfaces of the plurality of core modules, the dummy substrate facing the side surfaces of the plurality of core modules, at least some core modules of the plurality of core modules differ from remaining core modules of the plurality of core modules in at least one of a number of rows or columns of the core wiring arranged in the plan view parallel to the first redistribution structure, and a portion of a side surface of the dummy substrate, a portion of a side surface of the encapsulant, and a portion of a side surface of the first redistribution structure are coplanar with each other.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is a plan view of the semiconductor package of FIG. 1, taken along line I-I′;

FIG. 3 is a view illustrating a process of manufacturing a core module included in a semiconductor package, according to an embodiment;

FIG. 4 is a view illustrating a process of manufacturing a core module included in a semiconductor package, according to an embodiment;

FIG. 5 is a view illustrating a process of manufacturing a dummy substrate included in a semiconductor package, according to an embodiment;

FIG. 6 is a view illustrating a process of manufacturing a core structure included in a semiconductor package, according to an embodiment;

FIG. 7A, FIG. 7B, FIG. 7C, and FIG. 7D are views illustrating a process of manufacturing a semiconductor package, according to an embodiment;

FIG. 8 is a cross-sectional view of a semiconductor package according to an embodiment;

FIG. 9 is a cross-sectional view of a semiconductor package according to an embodiment;

FIG. 10 is a view illustrating a process of manufacturing a core module included in a semiconductor package, according to an embodiment;

FIG. 11 is a plan view of the semiconductor package of FIG. 9, taken along line I-I′; and

FIG. 12 is a plan view of a semiconductor package according to an embodiment.

### DETAILED DESCRIPTION

Hereinafter, embodiments of the inventive concept are described in detail with reference to the accompanying drawings. Like components are denoted by like reference numerals in the drawings, and redundant descriptions thereof may be omitted.

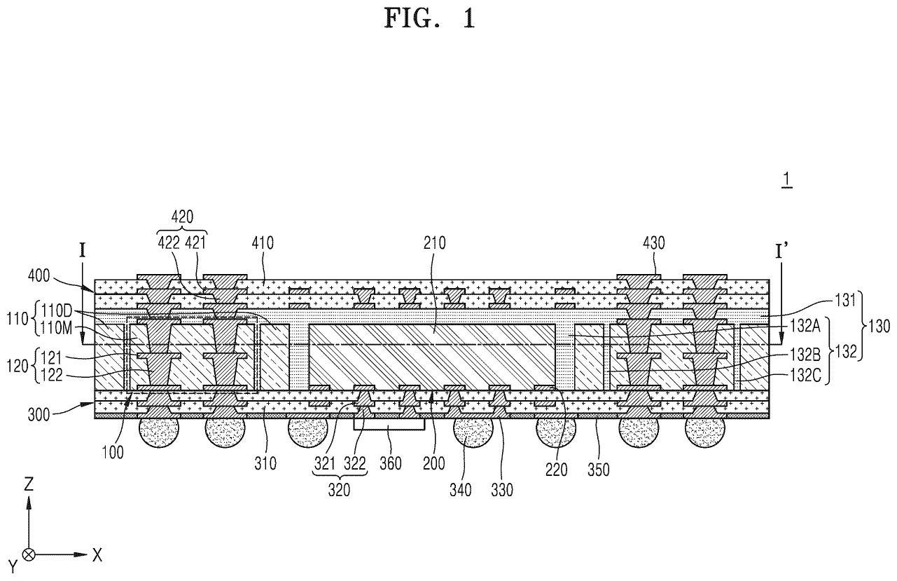

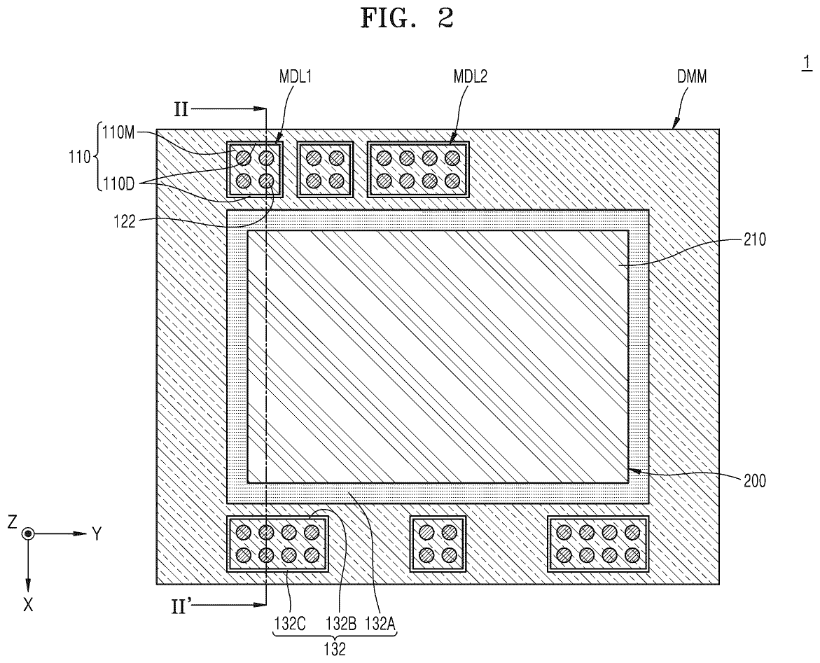

FIG. 1 is a cross-sectional view illustrating a semiconductor package 1 according to an embodiment. FIG. 2 is a plan view of the semiconductor package 1 of FIG. 1, taken along line I-I′.

According to an embodiment and referring to FIG. 1 and FIG. 2, the semiconductor package 1 may include a core module 100 and a dummy substrate 110D, a semiconductor chip 200, a first redistribution structure 300, an encapsulant 130, and a second redistribution structure 400. The core module 100 and the dummy substrate 110D may be referred to as a core structure. Herein, the first redistribution structure 300 and the second redistribution structure 400 may be referred to as a first substrate and a second substrate, respectively.

The first redistribution structure 300 may be arranged under the semiconductor chip 200. The first redistribution structure 300 may redistribute signals received from chip pads 220 of the semiconductor chip 200 to an external area of the semiconductor chip 200. Similarly, the first redistribution structure 300 may redistribute signals received from the external area of the semiconductor chip 200 to chip pads 220. In detail, the first redistribution structure 300 may include a lower insulating layer 310 and a first redistribution pattern 320. The first redistribution pattern 320 may include a first redistribution line pattern 321 and a first redistribution via pattern 322. The first redistribution line pattern 321 may be disposed on the first redistribution via pattern 322. The first redistribution line pattern 321 may be formed in a multi-layer structure, and the multiple layers of the first redistribution line pattern 321 may be connected to each other by the first redistribution via pattern 322.

The lower insulating layer 310 may include an insulating material, for example, photo-imageable dielectric (PID) resin, and may further include an inorganic filler. The lower insulating layer 310 may have a multi-layer structure. A multi-layer structure of the lower insulating layer 310 may be disposed according to the multi-layer structure of the first redistribution line pattern 321. In FIG. 1, for convenience, the lower insulating layer 310 is shown as having a two-layer structure. The first redistribution via pattern 322 may be formed on and penetrating a lower surface of a first layer of the lower insulating layer 310 and the first redistribution line pattern 321 may be formed on and penetrating a lower surface of a second layer of the lower insulating layer 310. When the lower insulating layer 310 has a multi-layer structure, the multiple layers of the lower insulating layer 310 may include the same material or different materials. Alternatively, the lower insulating layer 310 may have a single-layer structure.

An external connection pad 330 may be formed on a lower surface of the lower insulating layer 310. An external connection terminal 340 may be arranged on the external connection pad 330. The external connection terminal 340 may be arranged on the external connection pad 330 opposite to the lower insulating layer 310. The external connection terminal 340 may be electrically connected to the chip pads 220 through the first redistribution line pattern 321 of the first redistribution structure 300. A passive element 360 may be arranged on a lower surface of the first redistribution structure 300. The passive element 360 may include a capacitor, an inductor, a resistor, or the like. The passive element 360 may be electrically connected to other components.

As shown in FIG. 1, the external connection pad 330 and the external connection terminal 340 may be arranged on a portion corresponding to a lower surface of the semiconductor chip 200 and a portion extending outwardly in a first direction (e.g., the X direction) and a second direction (e.g., the Y direction) on the lower surface of the semiconductor chip 200. As a result, the first redistribution structure 300 may function to receive a signal from, or provide a signal to the chip pads 220 of the semiconductor chip 200 through the external connection pads 330 arranged over a relatively wide area greater than an area of the lower surface of the semiconductor chip 200. Similarly, the first redistribution structure 300 may function to provide power to the chip pads 220 of the semiconductor chip 200. As such, a package structure in which the external connection terminal 340 may be widely arranged beyond the lower surface of the semiconductor chip 200. This package structure may be referred to as a fan-out (FO) package structure.

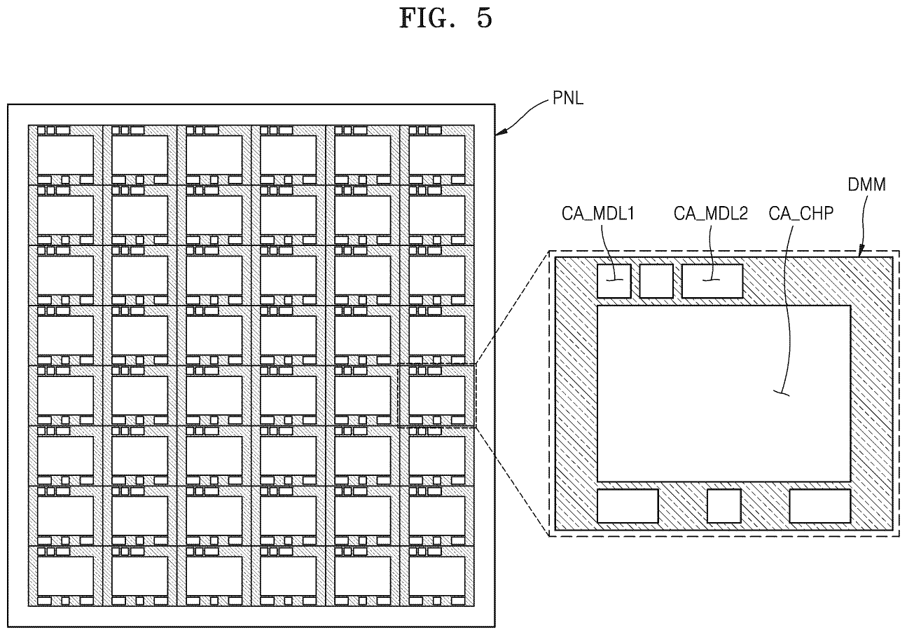

The semiconductor chip 200 may include a semiconductor substrate 210 and the chip pads 220. The semiconductor chip 200 may be arranged in a chip cavity CA_CHP (see FIG. 5) inside the core structure. That is, the semiconductor chip 200 may be mounted between inner side walls of the dummy substrate 110D that face each other. The semiconductor chip 200 may have a quadrangular space, but is not limited thereto. A side surface of the semiconductor chip 200 may be spaced apart from and face an inner side surface of the dummy substrate 110D.

The semiconductor chip 200 may include a logic semiconductor chip and/or a memory semiconductor chip. For example, the logic semiconductor chip may be an application processor (AP), a microprocessor, a central processing unit (CPU), a controller, an application-specific integrated circuit (ASIC), or the like. Also, the memory semiconductor chip may be, for example, a volatile memory, such as dynamic random access memory (DRAM) or static random access memory (SRAM), or a non-volatile memory, such as flash memory.

The semiconductor chip 200 may include the chip pads 220 arranged on a lower surface of the semiconductor substrate 210. The chip pads 220 and the lower surface of the semiconductor substrate 210 may be coplanar. Although not illustrated, the chip pads 220 may be disposed on the lower surface of the semiconductor substrate 210. According to an embodiment and in the semiconductor package 1, the lower surface of the semiconductor substrate 210, on which the chip pads 220 are arranged, may be an active surface, and an upper surface of the semiconductor substrate 210, which is opposite to the lower surface of the semiconductor substrate 210, may be an inactive surface. The chip pads 220 may be electrically connected to other components in the semiconductor chip 200, for example, an integrated circuit. Multiple wiring layers may be formed on the lower surface of the semiconductor substrate 210, and the chip pads 220 may be electrically connected to an internal integrated circuit through the multiple wiring layers.

The core structure may include the dummy substrate 110D and the core module 100. The core module 100 may include a module substrate 110M and a core wiring 120. The core wiring 120 may include a core pattern 121 and a core via 122. The dummy substrate 110D and the module substrate 110M may be collectively referred to as a core substrate 110. The core pattern 121 may be formed in a multi-layer structure, and the multiple layers of the core pattern 121 may be electrically connected to each other through the core via 122. In FIG. 1, the core pattern 121 is a two-layer structure, but the number of layers of the core pattern 121 is not limited to two. The module substrate 110M may have a multi-layer structure corresponding to the multi-layer structure of the core pattern 121. An uppermost surface of the module substrate 110M may be coplanar with an upper surface of the dummy substrate 110D. In FIG. 1, for convenience, the module substrate 110M is shown as a single layer.

The module substrate 110M may include an insulating material, for example, thermosetting resin, such as epoxy resin, or thermoplastic resin, such as polyimide, and may further include an inorganic filler. The module substrate 110M may include, in addition to the inorganic filler, resin impregnated into a core material, such as glass fiber, glass cloth, or glass fabric, for example, prepreg, AJINOMOTO BUILD-UP FILM® (ABF), flame retardant 4 (FR-4), bismaleimide triazine (BT), or the like.

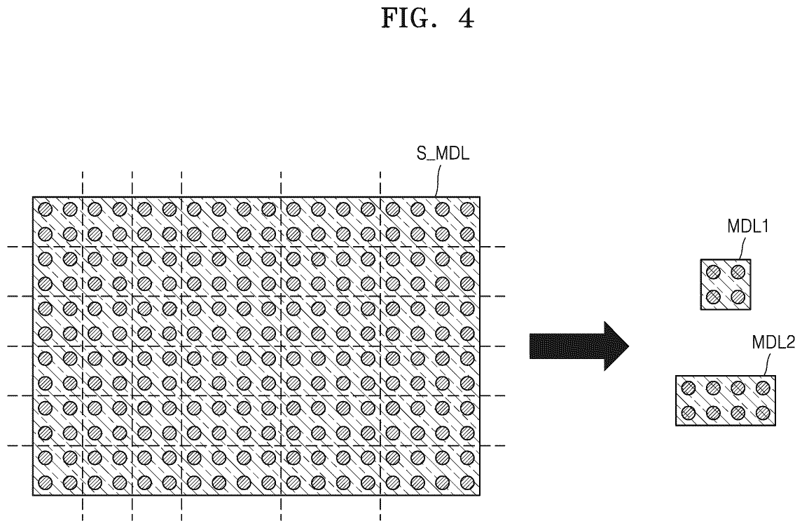

The dummy substrate 110D may include the same material or a different material from the module substrate 110M. The dummy substrate 110D may be manufactured simultaneously with, or separately from the module substrate 110M. In a conventional semiconductor package, a core pattern and a core via may be provided on one substrate, without distinguishing between a dummy substrate and the module substrate. In the semiconductor package 1 according to an embodiment, core modules MDL1 and MDL2 (see FIG. 4) may be disposed in module cavities CA_MDL1 and CA_MDL2 of the dummy substrate 110D (see FIG. 5), thereby forming a core structure. Detailed descriptions on a process of forming a core module and core structure are provided herein.

The core module 100 may be disposed in a cavity of the dummy substrate 110D and mounted on the first redistribution structure 300. Inner side surfaces of the dummy substrate 110D, which face side surfaces of the core module 100, may be spaced apart from the side surfaces of the core module 100. For example, a horizontal width of a gap between the inner side surfaces of the dummy substrate 110D, which face the side surfaces of the core module 100, and the side surfaces of the core module 100 may be from about 1 micrometers (μm) to about 5 μm.

The encapsulant 130 may be provided between the dummy substrate 110D and the core module 100, and between the dummy substrate 110D and the semiconductor chip 200. The encapsulant 130 may include an upper encapsulant 131 and a recessed encapsulant 132 extending downward from the upper encapsulant 131. The upper encapsulant 131 may be arranged on an upper surface of the semiconductor chip 200, an upper surface of the dummy substrate 110D, and an upper surface of the core module 100, and may be in contact with a lower surface of the second redistribution structure 400.

The recessed encapsulant 132 may be provided between the dummy substrate 110D and the core module 100, and between the dummy substrate 110D and the semiconductor chip 200, may include a first recessed encapsulant 132A, a second recessed encapsulant 132B, and a third recessed encapsulant 132C. The first recessed encapsulant 132A between the semiconductor chip 200 and the dummy substrate 110D, the second recessed encapsulant 132B that is closer to the semiconductor chip 200 among the encapsulants recessed between the dummy substrate 110D and the core module 100, and the third recessed encapsulant 132C that is farther from the semiconductor chip 200 among the encapsulants recessed between the dummy substrate 110D and the core module 100 may be shown in the cross-section of FIG. 1.

The dummy substrate 110D may be spaced apart from all side surfaces of the core module 100, as shown in FIG. 2, or one or more side surfaces of the core module 100 may be in contact with the dummy substrate 110D. When one or more side surfaces of the core module 100 are in contact with the dummy substrate 110D, recessing of the encapsulant 130 may not occur in a portion where the core module 100 is in contact with the dummy substrate 110D.

The encapsulant 130 may seal the semiconductor chip 200, thereby reducing or preventing external physical/chemical damage to the semiconductor chip 200. The encapsulant 130 may surround the side and upper surfaces of the semiconductor chip 200. The encapsulant 130 may be provided between a side surface of the dummy substrate 110D and the side surface of the semiconductor chip 200.

The encapsulant 130 may fill at least a portion of a space between the semiconductor chip 200 and the first redistribution structure 300. The encapsulant 130 may include an insulating material, for example, epoxy resin or polyimide. However, the material of the encapsulant 130 is not limited to the materials described above.

The second redistribution structure 400 may be disposed on the core structure and the encapsulant 130. The second redistribution structure 400 may be electrically connected to the semiconductor chip 200 and the first redistribution structure 300 through the core pattern 121 and the core via 122 of the core structure. Accordingly, the second redistribution structure 400 may receive a signal from, or provide a signal to the chip pads 220 of the semiconductor chip 200.

The second redistribution structure 400 may include an upper insulating layer 410 and a second redistribution pattern 420. The second redistribution pattern 420 may include a second redistribution line pattern 421 and a second redistribution via pattern 422. At least a portion of the second redistribution pattern 420 may be electrically connected to the core pattern 121 of the core structure. FIG. 1 shows a case in which the upper insulating layer 410 has two layers, but the second redistribution structure 400 may be formed as a single layer or as two or more upper insulating layers 410 that may be stacked. In an embodiment, the second redistribution pattern 420 may include one or more layers, and the layers of the second redistribution pattern 420 may correspond to layers of the upper insulating layer 410. For example, an upper instance of the second redistribution pattern 420 may include an upper connection pad 430, which may be a portion of the second redistribution line pattern 421.

The second redistribution structure 400 may include a conductive material, for example, copper (Cu), aluminum (Al), silver (Ag), tin (Sn), gold (Au), nickel (Ni), lead (Pb), titanium (Ti), or an alloy thereof. The second redistribution via pattern 422 may include a seed layer and a filling conductive layer. The second redistribution via pattern 422 may have an interior completely filled with a conductive material. However, the structure of the second redistribution via pattern 422 is not limited thereto. For example, in the second redistribution via pattern 422, a conductive material may be formed only along inner walls of the vias. The second redistribution via pattern 422 may have, for example, a tapered pillar shape, a cylindrical pillar, an elliptical pillar, or a polygonal pillar.

A first passivation layer 350 may be disposed on the lower surface of the first redistribution structure 300. Similarly, although not shown, a second passivation layer may be disposed on an upper surface of the second redistribution structure 400. The first passivation layer 350 may cover and protect the first redistribution structure 300. The second passivation layer may cover and protect the second redistribution structure 400. The first passivation layer 350 and the second passivation layer may each include an insulating material, for example, resin. The material of the first passivation layer 350 and the second passivation layer is not limited to resin.

The external connection pad 330 may be connected to the first redistribution line pattern 321 exposed through openings of the first passivation layer 350, and the external connection terminal 340 may be disposed on the external connection pad 330. Accordingly, the external connection terminal 340 may be electrically connected to the first redistribution line pattern 321 of the first redistribution structure 300. The external connection terminal 340 may connect the semiconductor package 1 to a main board or the like of an electronic device on which the semiconductor package 1 is mounted. The external connection terminal 340 may include a conductive material, for example, at least one of solder, tin (Sn), silver (Ag), copper (Cu), or aluminum (Al).

A portion of the second redistribution line pattern 421 may be exposed on the upper insulating layer 410 and may function as the upper connection pad 430. An inter-package connection terminal may be disposed on the upper connection pad 430, and at least one upper package may be disposed on the semiconductor package 1 through the inter-package connection terminal, thereby realizing a package-on-package (POP) structure.

FIG. 1 is a cross-sectional view of the semiconductor package 1 according to an embodiment, taken along line II-II′ of the plan view of FIG. 2. The core module 100 described with reference to FIG. I may be one of a first module MDL1 and a second module MDL2 shown in FIG. 2. The dummy substrate 110D described with reference to FIG. 1 may be a dummy substrate DMM shown in FIG. 2.

As shown in FIG. 2, the first module MDL1 and the second module MDL2 may be disposed on a first side portion and a second side portion of the semiconductor chip 200 along an X-axis. The first side portion may be a left portion in FIG. 1 and an upper portion in FIG. 2, and the second side portion may be a right portion in FIG. 1 and a lower portion in FIG. 2. On each of the first side portion and the second side portion of the semiconductor chip 200, the first module MDL1 and the second module MDL2 may also be variously disposed along a Y-axis, with respect to the semiconductor chip 200. Accordingly, when manufacturing the semiconductor package 1 according to an embodiment, by appropriately arranging the core module 100, which has been previously manufactured, in the dummy substrate 110D, a wiring arrangement of the semiconductor package 1 may be achieved. Accordingly, by arranging an appropriate number of cavities, into which the core module 100 may be disposed, at appropriate locations in the dummy substrate DMM, core structures having various structures may be produced and the semiconductor package 1 may be manufactured. As a result, the productivity of the semiconductor package 1 according to an embodiment may be improved.

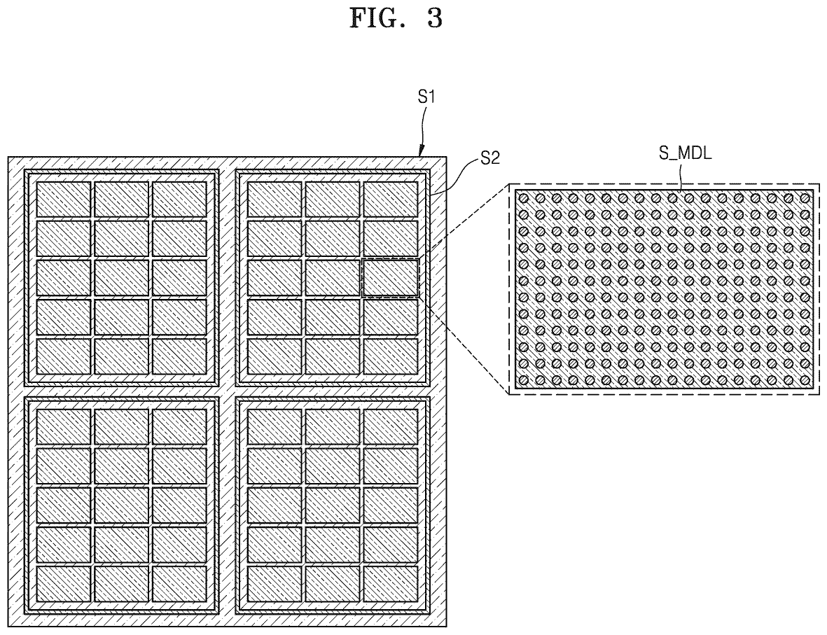

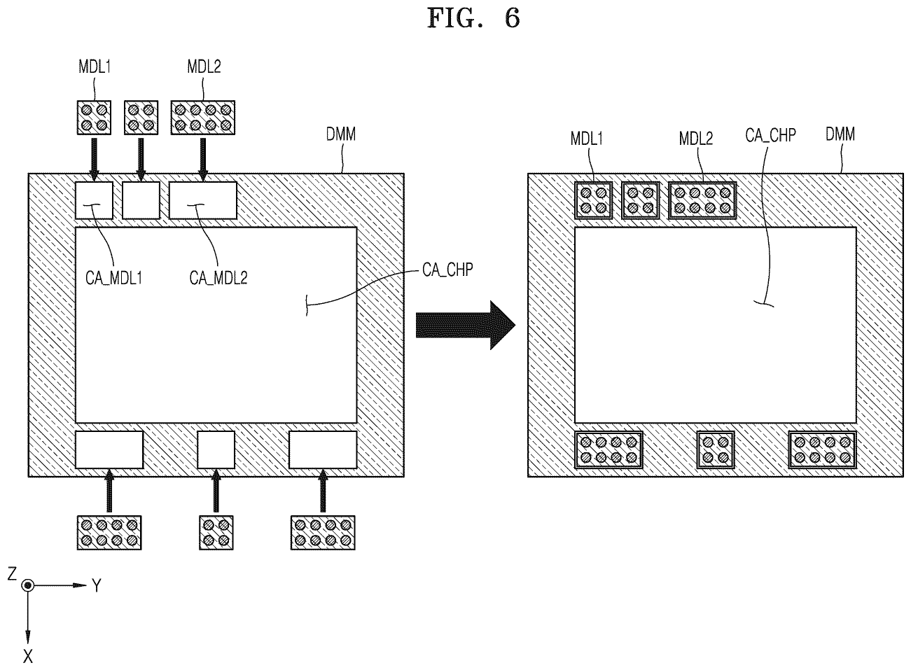

FIG. 3 is a view illustrating a process of manufacturing a core module included in the semiconductor package 1, according to an embodiment. FIG. 4 is a view illustrating a process of manufacturing a core module included in the semiconductor package 1, according to an embodiment. FIG. 5 is a view illustrating a process of manufacturing a dummy substrate included in the semiconductor package 1, according to an embodiment. FIG. 6 is a view illustrating a process of manufacturing a core structure included in the semiconductor package 1, according to an embodiment.

Referring to FIG. 3, a first module substrate S1 may be manufactured to include a plurality of second module substrates S2. The second module substrate S2 may include a module base substrate S_MDL in which stacked core wiring and core vias may be disposed in a plurality of rows and a plurality of columns in a plan view parallel to an upper surface of the first module substrate S1. The first module substrate S1 may be cut and divided into a plurality of second module substrates S2. The second module substrate S2 may also be cut and divided into a plurality of module base substrates S_MDL. FIG. 3 shows a case in which the first module substrate S1 may be cut to form the second module substrate S2 and the second module substrate S2 may be divided to form the module base substrate S_MDL, but the number of substrate cutting processes may be greater or less than that shown in the example, and thus, a manufacturing method is not limited thereto.

Referring to FIG. 4, a plurality of first modules MDL1 and a plurality of second modules MDL2 may be manufactured by cutting the module base substrate S_MDL. For example, as shown in FIG. 4, the module base substrate S_MDL may be cut and divided into the first module MDL1, in which stacked core wiring and core vias may be disposed in two rows and two columns in a plan view, and the second module MDL2, in which stacked core wiring and core vias may be disposed in two rows and four columns in a plan view. The drawing shows that a total of 18 first modules MDL1 and 18 second modules MDL2 may be manufactured from one module base substrate S_MDL, but the inventive concept is not limited thereto. The first module MDL1 and the second module MDL2 that have been manufactured may be transported to other semiconductor package manufacturing apparatus or facilities through reel tape or the like.

Referring to FIG. 5, a plurality of dummy substrates DMM may be formed on a panel PNL. The dummy substrate DMM may have a chip cavity CA_CHP in which a semiconductor chip may be disposed at the center of the dummy substrate DMM. The core structure, and more particularly the dummy substrate DMM may have a frame-like shape in a plan view, with respect to a semiconductor chip to be disposed in the chip cavity CA_CHP. The frame-like shape may define a center portion of the dummy substrate DMM in which a semiconductor chip may be disposed. Herein, a case in which a single semiconductor chip is arranged in the chip cavity CA_CHP is described as an example, but a plurality of semiconductor chips may be disposed in the chip cavity CA_CHP.

The dummy substrate DMM may have a first module cavity CA_MDL1 in which the first module MDL1 may be disposed and a second module cavity CA_MDL2 in which the second module MDL2 may be disposed. In an embodiment, as shown in FIG. 5, the dummy substrate DMM may have the first module cavity CA_MDL1 and the second module cavity CA_MDL2 in first side portions and second side portions of the dummy substrate DMM. The first side portions and the second side portions may be opposite each other relative to corresponding chip cavities CA_CHP. While not illustrated in FIG. 5, the dummy substrate DMM may have the first module cavity CA_MDL1 and the second module cavity CA_MDL2 in the first side portions and the second side portions of the dummy substrate DMM, and also in third side portions and fourth side portions of the dummy substrate DMM. The third side portions and the fourth side portions may be opposite each other relative to corresponding chip cavities CA_CHP, and may be disposed perpendicular to the first side portions and the second side portions. The third side portions and the fourth side portions may be left portions and right portions of the dummy substrates DMM in FIG. 5, respectively. The arrangement of module cavities in the dummy substrate DMM may be selected as needed and is not limited to the example of FIG. 5.

Referring to FIG. 6, the first module MDL1 and the second module MDL2 may be respectively disposed in the first module cavity CA_MDL1 and the second module cavity CA_MDL2 described above with reference to FIG. 5. For example, as shown in FIG. 6, two first modules MDL1 and one second module MDL2 may be respectively disposed in two first module cavities CA_MDL1 and one second module cavity CA_MDL2 in the first side portions of the dummy substrate DMM. One first module MDL1 and two second modules MDL2 may be respectively disposed in one first module cavity CA_MDL1 and two second module cavities CA_MDL2 in the second side portions of the dummy substrate DMM.

The process of disposing the first module MDL1 and the second module MDL2 in the first module cavity CA_MDL1 and the second module cavity CA_MDL2 may include inserting and arranging the first module MDL1 and the second module MDL2. The process of disposing the first module MDL1 and the second module MDL2 in the first module cavity CA_MDL1 and the second module cavity CA_MDL2 may be performed together in the process of disposing the semiconductor chip in the chip cavity CA_CHP. Alternatively, the process of disposing the first module MDL1 and the second module MDL2 in the first module cavity CA_MDL1 and the second module cavity CA_MDL2 may be performed before or after the process of disposing the semiconductor chip in the chip cavity CA_CHP.

In the semiconductor package 1 according to an embodiment, because core modules included in a core structure are manufactured separately from the core structure rather than being integrated with the core structure, after it is first determined whether or not the core modules are defective, only good core modules may be provided to a dummy substrate, and thus, the productivity of the semiconductor package 1 may be improved.

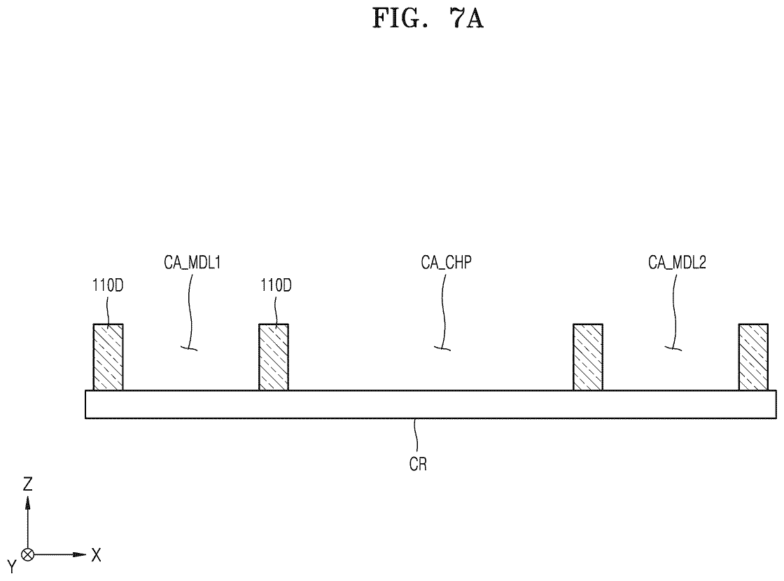

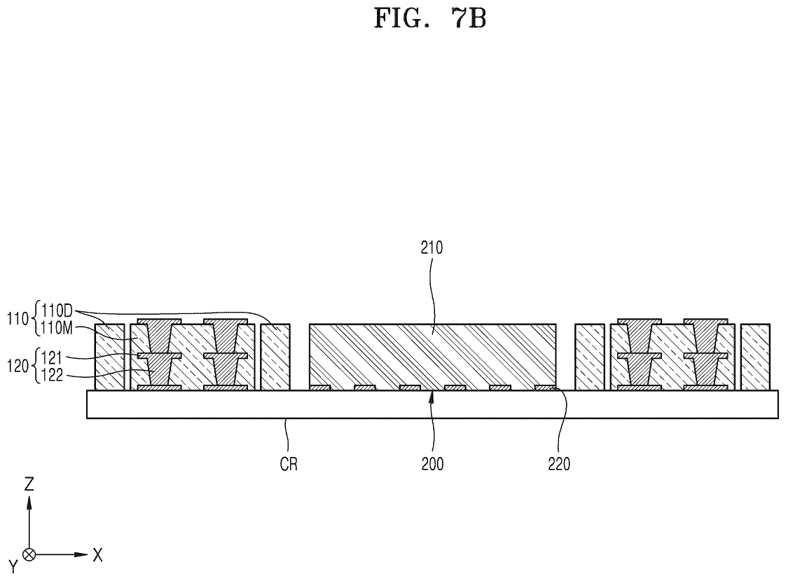

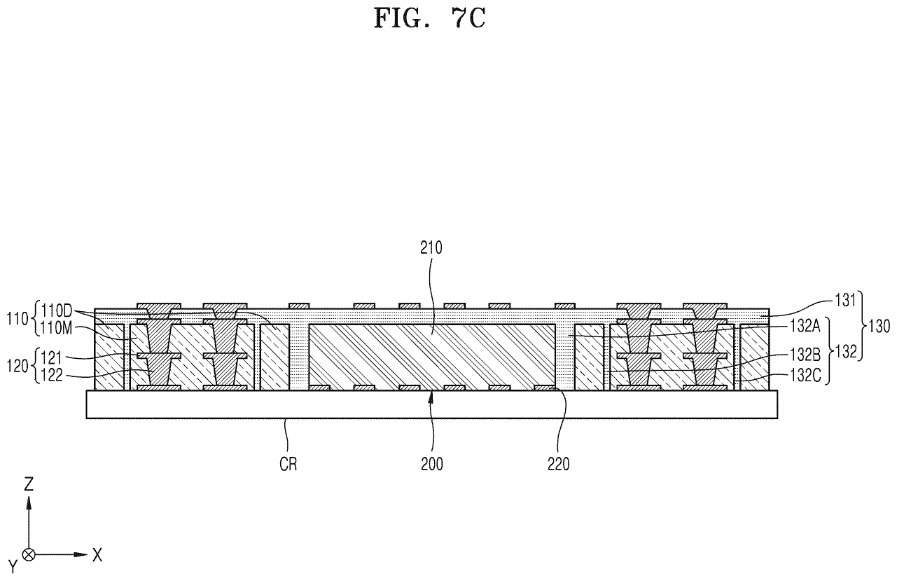

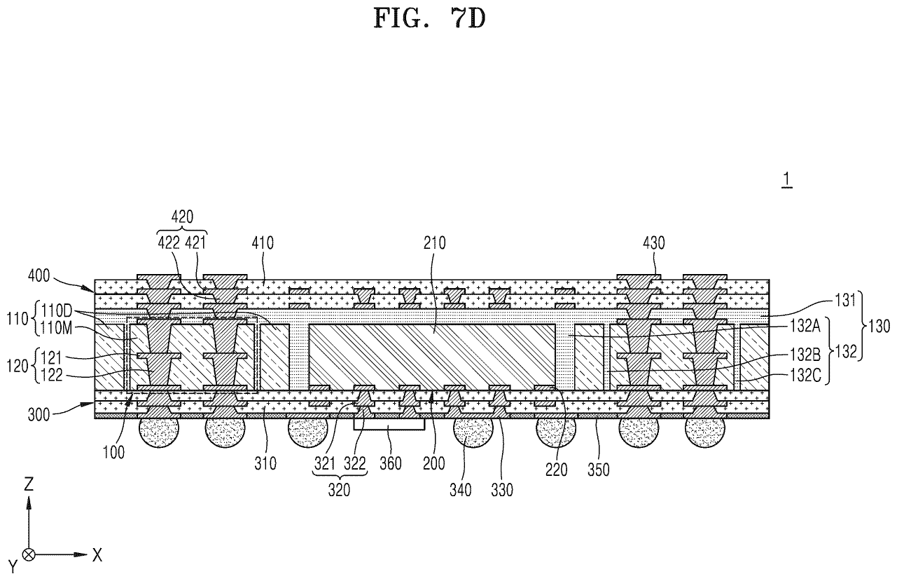

FIG. 7A, FIG. 7B, FIG. 7C, and FIG. 7D are views illustrating a process of manufacturing the semiconductor package 1, according to an embodiment. Descriptions that are redundant to those provided above may be omitted.

Referring to FIG. 7A, the dummy substrate 110D may be disposed on a carrier substrate CR. The dummy substrate 110D may be the same as the dummy substrate DMM described with reference to FIG. 5.

Referring to FIG. 7B, in FIG. 7A, the semiconductor chip 200, the first module MDL1, and the second module MDL2 may be respectively disposed in the chip cavity CA_CHP, the first module cavity CA_MDL1, and the second module cavity CA_MDL2 of the dummy substrate 110D, to be disposed on the carrier substrate CR. The first module MDL1 and the second module MDL2 may be mounted on the carrier substrate CR after the semiconductor chip 200 is mounted on the carrier substrate CR, the semiconductor chip 200 may be mounted on the carrier substrate CR after the first module MDL1 and the second module MDL2 are mounted on the carrier substrate CR, or the semiconductor chip 200, the first module MDL1, and the second module MDL2 may be mounted on the carrier substrate CR in the same process.

Referring to FIG. 7C, the encapsulant 130 may surround side and upper surfaces of the semiconductor chip 200 and may surround a portion of a side surface of the core substrate 110 and an upper surface of the core substrate 110. A portion of the encapsulant 130 may be recessed to form a conductive via for electrically connecting the encapsulant 130 to the second redistribution structure 400, and a conductive pad connected to the conductive via may be disposed on the conductive via.

Referring to FIG. 7D, the second redistribution structure 400 may be formed in the process result of FIG. 7C through a redistribution process, and the carrier substrate CR may be removed. The first redistribution structure 300 may be formed on a lower surface of the core substrate 110, a lower surface of the encapsulant 130, and a lower surface of the semiconductor chip 200 through a redistribution process. The external connection pad 330 may be formed on a lower surface of the lower insulating layer 310, and the external connection terminal 340 may be formed on the external connection pad 330.

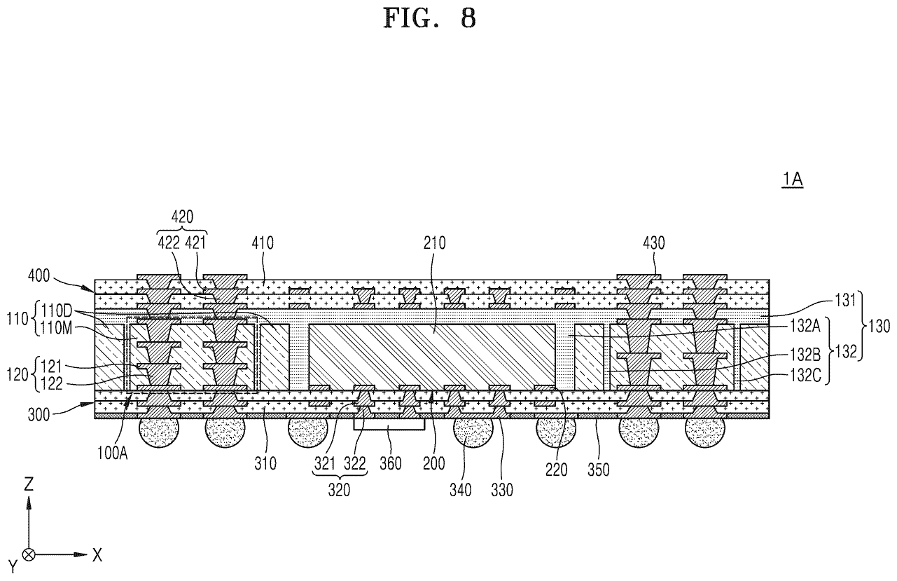

FIG. 8 is a cross-sectional view of a semiconductor package 1A according to an embodiment. Descriptions that are redundant to those provided above may be omitted.

Referring to FIG. 8, a core module 100A may have a different number of stacks from another core module. In an embodiment, in FIG. 8, the core module 100A on the left may be a core module in which three core wirings 120 are stacked vertically, and a core module on the right may be a core module in which two core wirings 120 are stacked vertically. That is, core modules with different numbers of core wirings in the stacks may be mounted on the semiconductor package 1A according to an embodiment. Because core modules with different numbers of core wirings in the stacks may be disposed in the dummy substrate 110D, according to the arrangements and designs of the semiconductor chip 200, an external semiconductor device (not shown) that may be mounted on an upper portion of the semiconductor package 1A, and the external connection pad 330 and the external connection terminal 340 that are electrically connected to the outside, the design of the semiconductor package 1A may be easier.

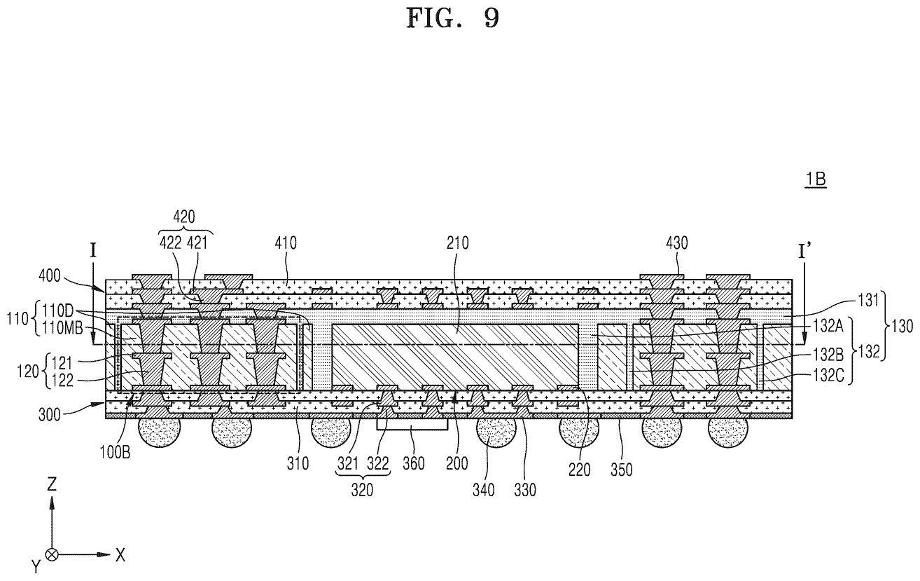

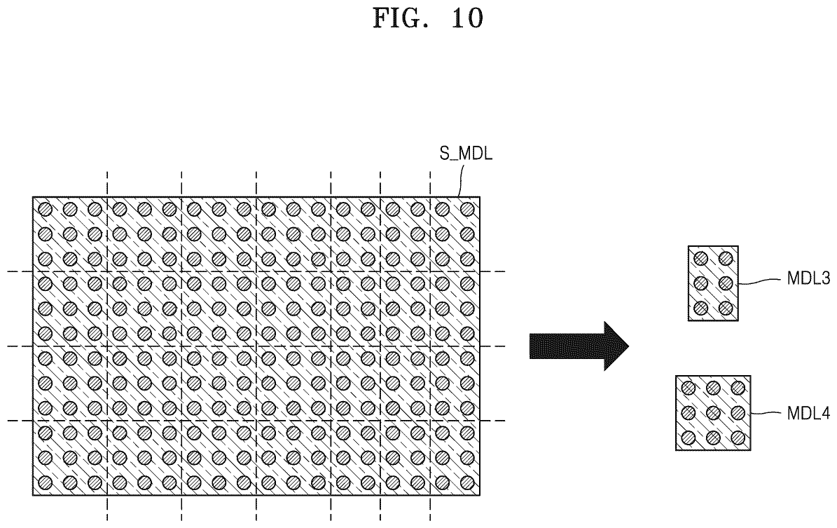

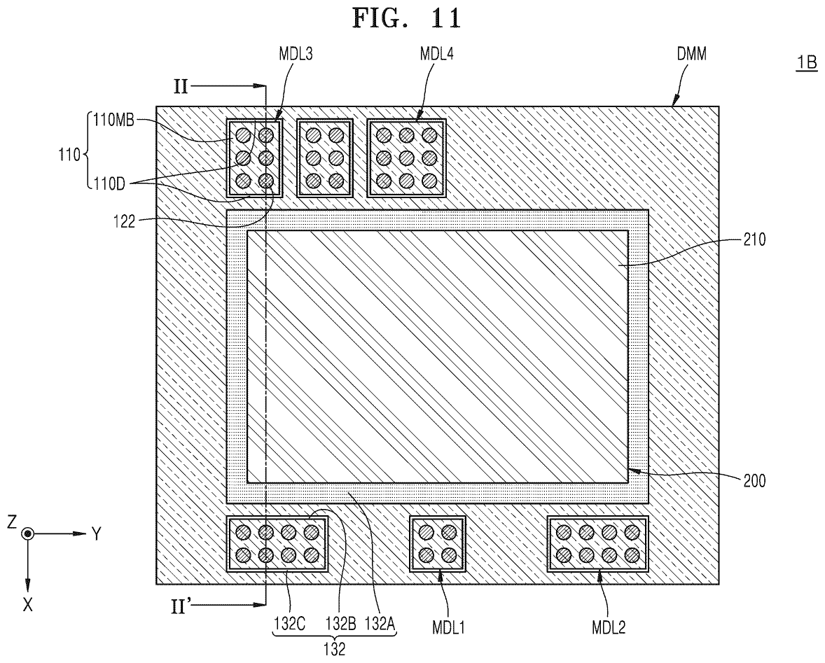

FIG. 9 is a cross-sectional view of a semiconductor package 1B according to an embodiment. FIG. 10 is a view illustrating a process of manufacturing a core module included in the semiconductor package 1B, according to an embodiment. FIG. 11 is a plan view of the semiconductor package 1B of FIG. 9, taken along line I-I′. Descriptions that are redundant to those provided above may be omitted.

Referring to FIG. 9, FIG. 10, and FIG. 11, as shown in FIG. 9, the semiconductor package 1B according to an embodiment may include core modules in which the core wirings 120 are vertically stacked around the semiconductor chip 200. A number of the core modules may be disposed in a lateral direction (e.g., the X direction and/or the Y direction). In an embodiment, as shown in FIG. 9, a core module 100B may include three core wiring 120 stacks disposed at a side the semiconductor chip 200. The core wiring 120 stacks of the core module 100B may be arranged in the lateral direction extending away from the semiconductor chip 200. A core module disposed opposite to the core module 100B relative to the semiconductor chip 200 may include two core wiring 120 stacks disposed at a side the semiconductor chip 200 and arranged in the lateral direction extending away from the semiconductor chip 200. That is, different core modules may include different numbers of core wiring 120 stacks, and the core modules may be disposed in the dummy substrate 110D.

A core module with a larger number of core wiring 120 stacks may have a greater lateral width than a core module with a smaller number of core wiring 120 stacks. For example, as shown in FIG. 9, a core substrate 110MB of the core module 100B on the first side has a large lateral width, and thus, the width of the dummy substrate 110D adjacent thereto is relatively narrower than that of the dummy substrate 110D adjacent to the core module on the second side. Even when the width of a core module is large, the size of the semiconductor package 1B may be adjusted by adjusting the width of the dummy substrate 110D. Core modules with different numbers of core wiring 120 stacks disposed in the lateral direction may be disposed in the dummy substrate 110D, according to the arrangements and designs of the semiconductor chip 200, an external semiconductor device (not shown) that may be mounted on an upper portion of the semiconductor package 1B, and the external connection pad 330 and the external connection terminal 340 that are electrically connected to the outside, the design of the semiconductor package 1B may be easier.

Referring to FIG. 10, a plurality of third modules MDL3 and a plurality of fourth modules MDL4 may be manufactured by cutting the module base substrate S_MDL. For example, as shown in FIG. 10, the module base substrate S_MDL may be cut and divided into the third module MDL3, in which stacked core wiring and core vias may be disposed in three rows and two columns in a plan view, and the fourth module MDL4, in which stacked core wiring and core vias may be disposed in three rows and three columns in a plan view. The drawing shows that a total of 12 third modules MDL3 and 16 fourth modules MDL4 may be manufactured from one module base substrate S_MDL, but the inventive concept is not limited thereto. The third module MDL3 and the fourth module MDL4 that have been manufactured may be transported to other semiconductor package manufacturing apparatus or facilities through reel tape or the like. The subsequent manufacturing process(es) may be performed, for example, as described herein.

As shown in FIG. 11, two third modules MDL3 and one fourth module MDL4 may be disposed in the dummy substrate DMM on a first side portion the semiconductor chip 200. Also, one first module MDL1 and two second modules MDL2 may be disposed in the dummy substrate DMM on a second side portion of the semiconductor chip 200. The first side portion and the second side portion of the semiconductor chip 200 may be opposite side portions. That is, the semiconductor package 1B according to an embodiment may include at least one core module with a different number of rows or columns of the core wiring 120 disposed in a core module in a plan view. According to an embodiment, the semiconductor package 1B may include an improved design in which different core modules may be disposed in the dummy substrate 110D, according to the arrangements and designs of the semiconductor chip 200, an external semiconductor device (not shown) may be mounted on an upper portion of the semiconductor package 1B, and the external connection pad 330 and the external connection terminal 340 may electrically connected to the outside.

Different ones of the core modules may include different numbers of rows and/or columns of stacks of the core wiring 120. For example, the core wiring 120 of a first core module may be arranged in N rows and N columns, where N is a natural number of 2 or more, and the core wiring 120 of a second core module may be arranged in N rows and 2N columns. In another example, the core wiring 120 of a first core module may be arranged in N rows, where N is a natural number of 2 or more, and M columns, where M is a natural number of 2 or more, and the core wiring 120 of a second core module may be arranged in P rows, where P is a natural number of 2 or more, and Q columns, where Q is a natural number greater than M.

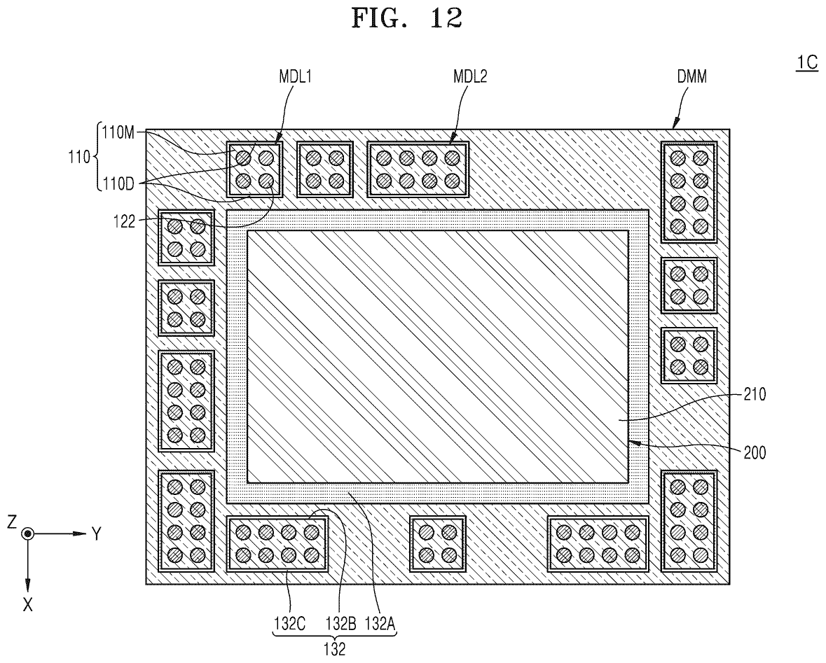

FIG. 12 is a plan view of a semiconductor package 1C. Descriptions that are redundant to those provided above may be omitted.

Referring to FIG. 12, core modules may be disposed on different side portions of the dummy substrate DMM, which are located in the first direction (X direction) and the second direction (Y direction) with respect to the semiconductor chip 200. For example, as shown in FIG. 12, two first modules MDL1 and one second module MDL2 may be disposed on the first side portion of the semiconductor chip 200, two first modules MDL1 and two second modules MDL2 may be disposed substantially along the fourth side portion of the semiconductor chip 200, one first module MDL1 and two second modules MDL2 may be disposed on the second side portion of the semiconductor chip 200, and two first modules MDL1 and two second modules MDL2 may be disposed substantially along the third side portion of the semiconductor chip 200. For example, one or more modules may be arranged alone a side portion of the semiconductor chip 200 and may extend beyond a corner of the semiconductor chip 200. A core module may be disposed on the dummy substrate DMM in any direction with respect to the semiconductor chip 200. Accordingly, by appropriately arranging a core module as needed, the production of the semiconductor package 1C may be more easily performed.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first substrate;
a first semiconductor device disposed on the first substrate;
a dummy substrate disposed on the first substrate, spaced apart from a side surface of the first semiconductor device, and surrounding the first semiconductor device;
a core module disposed in the dummy substrate; and
an encapsulant surrounding the first semiconductor device and in contact with the dummy substrate,
wherein the core module includes a core wiring and a module substrate,
the core module is disposed on the first substrate, and a side surface of the core module is surrounded by and spaced apart from an inner side surface of the dummy substrate, and
the encapsulant is disposed between the dummy substrate and the side surface of the core module.

2. The semiconductor package of claim 1, wherein a plurality of core modules, including the core module, are disposed in the dummy substrate and on the first substrate.

3. The semiconductor package of claim 2, wherein all side surfaces of each of the plurality of core modules are spaced apart from all inner side surfaces of the dummy substrate that face the side surfaces of each of the plurality of core modules.

4. The semiconductor package of claim 2, wherein an uppermost surface of the module substrate of the plurality of core modules is coplanar with an upper surface of the dummy substrate.

5. The semiconductor package of claim 2, wherein the core wiring of a first core module of the plurality of core modules includes a first stack of core wirings,
the core wiring of a second core module of the plurality of core modules includes a second stack of core wirings, and
the first stack of core wirings includes a first number of core wirings different from a second number of core wirings of the second stack of core wirings.

6. The semiconductor package of claim 2, wherein the plurality of core modules include the core wiring arranged in a plurality of rows and a plurality of columns in a plan view parallel to the first substrate.

7. The semiconductor package of claim 6, wherein at least some core modules of the plurality of core modules differ from remaining core modules of the plurality of core modules in at least one of a number of the rows or the columns of the core wiring.

8. The semiconductor package of claim 7, wherein the plurality of core modules include a first core module and a second core module,
the first core module includes the core wiring arranged in N rows and N columns, where N is a natural number of 2 or more, and
the second core module includes the core wiring arranged in N rows and 2N columns.

9. The semiconductor package of claim 7, wherein the plurality of core modules include a first core module and a second core module,
the first core module includes the core wiring arranged in N rows, where N is a natural number of 2 or more, and M columns, where M is a natural number of 2 or more, and
the second core module includes the core wiring arranged in P rows, where P is a natural number of 2 or more, and Q columns, where Q is a natural number greater than M.

10. The semiconductor package of claim 1, wherein the core wiring includes a core pattern and a core via.

11. The semiconductor package of claim 2, wherein the plurality of core modules all have a same number of stacks of the core wiring.

12. The semiconductor package of claim 1, further comprising a second substrate disposed on the encapsulant and electrically connected to the core module.

13. The semiconductor package of claim 12, wherein the first substrate and the second substrate are each a redistribution structure.

14. The semiconductor package of claim 2, wherein the plurality of core modules are disposed on a plurality of side surfaces of the first semiconductor device.

15. The semiconductor package of claim 14, wherein the first semiconductor device has a quadrangular shape, and the dummy substrate has a frame-like shape with the first semiconductor device disposed at a center portion thereof, and
the first semiconductor device has four side surfaces, and the plurality of core modules are disposed at two or more side portions of the dummy substrate.

16. A semiconductor package comprising:
a first substrate;
a first semiconductor device disposed on the first substrate;
a core structure disposed on the first substrate, spaced apart from a side surface of the first semiconductor device, and surrounding the first semiconductor device; and
an encapsulant surrounding the first semiconductor device and in contact with the core structure,
wherein the core structure includes a core module and a dummy substrate, the core module including a core wiring and a module substrate,
the core module is disposed on the first substrate, a side surface of the core module is surrounded by and spaced apart from an inner side surface of the dummy substrate, and the encapsulant is disposed between the dummy substrate and the side surface of the core module, the dummy substrate facing the side surface of the core module,
the first semiconductor device has a quadrangular shape, and the core structure has a frame-like shape with the first semiconductor device at a center portion thereof, and
the core module is provided on two or more side portions of the core structure that respectively face side surfaces of the first semiconductor device.

17. The semiconductor package of claim 16, wherein the dummy substrate and the module substrate include a same material.

18. The semiconductor package of claim 16, wherein a portion of a side surface of the dummy substrate, a portion of a side surface of the encapsulant, and a portion of a side surface of the first substrate are coplanar with each other.

19. The semiconductor package of claim 16, wherein a horizontal width between the dummy substrate and the side surface of the core module is about 1 micrometer (μm) to about 5 μm.

20. A semiconductor package comprising:
a first redistribution structure;
a first semiconductor device disposed on the first redistribution structure;
a core structure disposed on the first redistribution structure, spaced apart from a side surface of the first semiconductor device in a lateral direction, and surrounding the first semiconductor device, the lateral direction being a horizontal direction;
an encapsulant surrounding the first semiconductor device and in contact with the core structure; and
a second redistribution structure located on the encapsulant and electrically connected to the core structure,
wherein the core structure includes a plurality of core modules and a dummy substrate, each core module of the plurality of core modules including a core wiring and a module substrate, the core wiring being arranged in a plurality of rows and a plurality of columns in a plan view parallel to the first redistribution structure and including a core pattern and a core via,
an upper surface of the module substrate is coplanar with an upper surface of the dummy substrate, the plurality of core modules are disposed on the first redistribution structure, and side surfaces of the plurality of core modules are surrounded by and spaced apart from inner side surfaces of the dummy substrate,
the encapsulant is disposed between the dummy substrate and the side surfaces of the plurality of core modules, the dummy substrate facing the side surfaces of the plurality of core modules,
at least some core modules of the plurality of core modules differ from remaining core modules of the plurality of core modules in at least one of a number of rows or columns of the core wiring arranged in the plan view parallel to the first redistribution structure, and
a portion of a side surface of the dummy substrate, a portion of a side surface of the encapsulant, and a portion of a side surface of the first redistribution structure are coplanar with each other.
